(19) United States
(12) Patent Application Publication
(10) Pub. No.: US 2021/0010498 A1
(43) Pub. Date: Jan. 14, 2021

(54) METHOD OF MOUNTING FIXING ASSEMBLY TO WORKPIECE

(71) Applicant: DTECH PRECISION INDUSTRIES CO., LTD., New Taipei City (TW)

(72) Inventor: TING-JUI WANG, NEW TAIPEI CITY (TW)

(21) Appl. No.: 17/032,032

(22) Filed: Sep. 25, 2020

Related U.S. Application Data
(63) Continuation-in-part of application No. 15/352,707, filed on Nov. 16, 2016.

(30) Foreign Application Priority Data
Nov. 20, 2015 (TW) 104138651

(51) Int. Cl. F16B 5/02; F16B 5/08

(52) U.S. Cl. CPC F16B 5/0208; F16B 2200/506; F16B 5/08

(57) ABSTRACT

A method of mounting a fixing assembly to a workpiece is introduced. The fixing assembly includes a fastener structure, which consists of an engaging member and a mating member connected together, and a fastening member, which includes sequentially connected head portion, assembling section and fastening section, while the assembling section is assembled to the engaging member of the fastener structure. In the method of mounting the fixing assembly to a workpiece, the engaging member of the fastener structure is first connected to the mating member, the assembling section of the fastening member is then forced through an insertion-hole section of the engaging member to be assembled thereto, and finally, a first inner retaining section of the mating member is movably connected to an outer retaining section of a locating member, which is connected to the workpiece.

### CROSS-REFERENCE TO RELATED APPLICATION

This application is a continuation-in-part patent application of U.S. application Ser. No. 15/352,707, filed on Nov. 16, 2016, which claims priority to Taiwanese Application No. 104138651, filed on Nov. 20, 2015, the entire contents both of which are hereby incorporated by reference for which priority is claimed under 35 U.S.C. § 120.

### BACKGROUND OF THE INVENTION

### 1. Field of the Invention

The present disclosure relates to a method of mounting a fixing assembly to a workpiece; and more particularly, to a method for easily mounting a fixing assembly to a workpiece.

### 2. Description of the Related Art

Generally, a fixing assembly is used to connect two or more workpieces together and accordingly could not be easily manufactured. It is therefore tried by the inventor to develop a fastener structure for a fixing assembly, a fixing assembly, and a method of assembling the fixing assembly, so that the fixing assembly can have a simple structure and be completed in a simple way.

### BRIEF SUMMARY OF THE INVENTION

An objective of the present disclosure is to provide a method of mounting a fixing assembly to a workpiece, so that the fixing assembly can be mounted to the workpiece in a simple way.

To achieve at least the above objective, a first aspect of the present disclosure is to provide a fastener structure for a fixing assembly. The fastener structure according to an embodiment of the present disclosure includes an engaging member and a mating member connected together, and the engaging member is used to engage with a fastening member.

In the above fastener structure, the mating member is a hollow cylindrical body, or an assembly of the engaging member and the mating member is a hollow cylindrical body. The hollow cylindrical body internally defines a receiving space.

In the above fastener structure, the mating member has a first inner retaining section for movably connecting to a locating member.

In the above fastener structure, the first inner retaining section has a first pressing surface, which can be a flat surface, a bevel surface, a curved surface or a cambered surface.

In the above fastener structure, the first inner retaining section has a first retaining groove for movably retaining the locating member thereto.

In the above fastener structure, the first inner retaining section is made of a plastic material with elasticity.

In the above fastener structure, the mating member has a plurality of retaining tabs for movably retaining the locating member thereto.

In the above fastener structure, the mating member has an outer peripheral surface, which can be a smooth surface, an embossed surface, a serrated surface or a toothed surface.

In the above fastener structure, the engaging member has an insertion-hole section, through which the fastening member is extended to be held in place.

In the above fastener structure, the insertion-hole section of the engaging member can be provided with an upper extended section, a lower extended section, an upper recessed section or a lower recessed section.

In the above fastener structure, the engaging member has an outer peripheral surface, which can be embossed, serrated or toothed, or be provided with recessed portions or protruded portions, or be a flat surface, a bevel surface, a curved surface or a cambered surface for connecting to the mating member.

In the above fastener structure, the outer peripheral surface of the engaging member can be in the form of a circle, an odd-sided polygon or an even-sided polygon for connecting to the mating member.

In the above fastener structure, the engaging member can be connected at an upper portion, a lower portion and a side portion to the mating member, or the engaging member can be connected at an upper portion to the mating member, or the engaging member can be connected at a lower portion to the mating member, or the engaging member can be connected at a side portion to the mating member, or the engaging member can be connected at an upper portion and a lower portion to the mating member, or the engaging member can be connected at an upper portion and a side portion to the mating member, or the engaging member can be connected at a lower portion and a side portion to the mating member.

In the above fastener structure, the mating member is connected to the engaging member via plastic insertion molding.

In the above fastener structure, the mating member is connected to the engaging member by way of thermal bonding, riveting, expanded connection, glue bonding, screwing or welding.

In the above fastener structure, the engaging member is made of a plastic material or a metal material, and the mating member is made of a plastic material or a metal material.

In the above fastener structure, a first mold is provided. The first mold has a gate and a mating-member receiving space, which are communicable with each other. The engaging member is disposed in the first mold and is connected to the mating-member receiving space. Via the gate, a molten plastic material is injected into the mating-member receiving space to form the mating member, which is connected to the engaging member in the first mold.

In the above fastener structure, a carrier is further included for holding the fastener structure thereon. The carrier can be in the form of a tray or a belt.

In the above fastener structure, an assistant placement device is further included for disposing on a top of the fastener structure.

In the above fastener structure, the carrier has a covering member for covering the fastener structure disposed on the carrier.

To achieve at least the above objective, a second aspect of the present disclosure is to provide a fixing assembly. The fixing assembly according to an embodiment of the present disclosure includes a fastening member and the above-described fastener structure. The fastening member has a head portion, an assembling section and a fastening section, which are sequentially connected to one another. And, the assembling section is assembled to the engaging member.

In the above fixing assembly, the head portion of the fastening member can be located higher than, flush with or located lower than a top of the mating member.

In the above fixing assembly, the head portion of the fastening member has an outer peripheral surface, which can be a bevel surface, a cambered surface, or a curved surface.

In the above fixing assembly, the assembling section of the fastening member has an outer peripheral surface, which can be embossed, serrated or toothed, or be provided with recessed portions or protruded portions, or in the form of a flat surface, a bevel surface, a curved surface or a cambered surface, so that the assembling section can be correspondingly assembled to the engaging member by way of riveting, fastening, expanded connection, screwing, welding, glue bonding or thermal bonding.

In the above fixing assembly, the fastening member is integrally formed with the engaging member.

In the above fixing assembly, the fastening member is integrally formed with the engaging member by way of machining, forging, stamping, plastic injection molding or metal injection molding.

In the above fixing assembly, the fastening member, the engaging member and the mating member are integrally formed.

In the above fixing assembly, the engaging member and the mating member are integrally formed by way of machining, forging, stamping, plastic injection molding or metal injection molding.

In the above fixing assembly, the fastening section of the fastening member is in the form of male threads, female threads, a male retainer, a female retainer or a stem.

In the above fixing assembly, the engaging member, the mating member and the fastening member are assembled into a module.

In the above fixing assembly, the engaging member and the fastening member are integrally formed, and the mating member is connected to the engaging member through plastic insertion molding.

In the above fixing assembly, a carrier is further included for holding the fixing assembly thereon. The carrier can be in the form of a tray or a belt.

In the above fixing assembly, an assistant placement device is further included for disposing on a top of the fixing assembly.

In the above fixing assembly, the carrier has a covering member for covering the fixing assembly disposed on the carrier.

In the above fixing assembly, the fixing assembly further includes a locating member, and the locating member is movably connected to the fastening member or the mating member.

In the above fixing assembly, the locating member includes an outer retaining section for movably connecting to the first inner retaining section of the mating member.

In the above fixing assembly, the outer retaining section has a second retaining groove for movably engaging with the first inner retaining section.

In the above fixing assembly, the outer retaining section has a flat surface, a bevel surface, a curved surface or a cambered surface.

In the above fixing assembly, the locating member has a locating section, which can be connected to a workpiece by way of riveting, fastening, expanded connection, screwing, welding or glue bonding.

In the above fixing assembly, the engaging member, the mating member, the locating member and the fastening member can be assembled into a module.

In the above fixing assembly, the engaging member, the mating member, the locating member, the fastening member and the workpiece can be assembled into a module with the workpiece being connected to the locating member.

In the above fixing assembly, the locating member has a second inner retaining section for movably connecting to the fastening member.

In the above fixing assembly, a carrier is further included for holding the fixing assembly thereon. The carrier can be in the form of a tray or a belt.

In the above fixing assembly, an assistant placement device is further included for disposing on a top of the fixing assembly.

In the above fixing assembly, the carrier has a covering member for covering the fixing assembly disposed on the carrier.

In the above fixing assembly, the fixing assembly further includes an elastic element, which has an end pressed against the engaging member or the mating member and another end pressed against the locating member.

In the above fixing assembly, the engaging member, the mating member, the locating member, the fastening member and the elastic element can be assembled into a module.

In the above fixing assembly, the engaging member, the mating member, the locating member, the fastening member, the elastic element and the workpiece can be assembled into a module with the workpiece being connected to the locating member.

In the above fixing assembly, a carrier is further included for holding the fixing assembly thereon. The carrier can be in the form of a tray or a belt.

In the above fixing assembly, an assistant placement device is further included for disposing on a top of the fixing assembly.

In the above fixing assembly, the carrier has a covering member for covering the fixing assembly disposed on the carrier.

To achieve at least the above objective, a third aspect of the present disclosure is to provide a method of assembling a fixing assembly. The fixing assembly to be assembled is the same as the above-described fixing assembly. According to the assembling method, first connect the engaging member to the mating member and press the assembling section of the fastening member through the insertion-hole section of the engaging member; or first integrally form the engaging member and the fastening member and then connect the integrally formed engaging member and fastening member to the mating member, and then or simultaneously movably connect the first inner retaining section of the mating member to the outer retaining section of the locating member, or movably connect the fastening member to the second inner retaining section of the locating member.

To achieve the above and other objects, a fourth aspect of the present disclosure is to provide a method of assembling a fixing assembly. The fixing assembly to be assembled is the same as the above-described fixing assembly. According to the assembling method, first integrally form the engaging member, the mating member and the fastening member, or first integrally form the engaging member and the fastening member and then connect the integrally formed engaging member and fastening member to the mating member, and meanwhile connect the locating member to a workpiece by riveting, fastening, expanded connection, screwing, welding or glue bonding to form a module, and finally movably connect the first inner retaining section of the mating member to the outer retaining section of the locating member, or movably connect the fastening member to the second inner retaining section of the locating member.

In the above method of assembling a fixing assembly provided according to the third and the fourth aspect of the present disclosure, the first inner retaining section of the mating member is made of a plastic material with elasticity; whereby before the first inner retaining section of the mating member can be movably connected to the outer retaining section of the locating member, the first inner retaining section is first radially outward expanded to be diametrically larger than or equal to the outer retaining section and can therefore move across the outer retaining section; and once the first inner retaining section has moved across the outer retaining section, the first inner retaining section immediately elastically restores to its non-expanded position and is movably connected to the outer retaining section of the locating member.

In the above method of assembling a fixing assembly provided according to the fourth aspect of the present disclosure, an assistant assembling tool is provided to move the fastening section of the fastening member, so that the first inner retaining section is brought to be movably connected to the outer retaining section or the fastening member is brought to be movably connected to the locating member.

In the above method of assembling a fixing assembly provided according to the fourth aspect of the present disclosure, the assistant assembling tool is provided with internal threads, external threads, a through hole, protruded portions or recessed portions.

To achieve at least the above objective, a fifth aspect of the present disclosure is to provide a method for mounting a fixing assembly to a workpiece. The fixing assembly includes an engaging member, a mating member and a fastening member; and the engaging member is correspondingly connected to the mating member and to the fastening member. The method according to the fifth aspect of the present disclosure includes the following steps: providing a tool to pick up the fixing assembly; providing a comparison device to compare the fixing assembly with a mounting position on the workpiece or a mounting distance between the fixing assembly and the workpiece; using the tool to move the fixing assembly to a predetermined height directly above the mounting position on the workpiece based on comparison information provided by the comparison device; and releasing or loosening the fixing assembly from the tool, so that the fixing assembly is fallen to the mounting position on the workpiece.

In the method according to the fifth aspect of the present disclosure, the fixing assembly can be movably connected to the locating member.

In the method according to the fifth aspect of the present disclosure, the engaging member and the fastening member can be integrally formed with each other.

In the method according to the fifth aspect of the present disclosure, the tool may be a vacuum suction device, a pick-up device, a retaining device, a magnetic suction device, or a robotic arm.

In the method according to the fifth aspect of the present disclosure, the comparison device may be a charge-coupled device (CCD), a visual comparison device, an image comparison device, a distance comparison device or a computer comparison device.

In the method according to the fifth aspect of the present disclosure, the fixing assembly may include a weldable layer and the workpiece may be a printed circuit board (PCB) and have a corresponding weldable layer formed thereon. The tool may move the fixing assembly to a predetermined height directly above the corresponding weldable layer on the workpiece and then releases or loosens the fixing assembly from the tool, so that the fixing assembly is fallen to the corresponding weldable layer. Then, the weldable layer of the fixing assembly and the corresponding weldable layer of the workpiece are heated and welded to each other.

In the method according to the fifth aspect of the present disclosure, the locating member may include a weldable layer and the workpiece may be a printed circuit board (PCB) and have a corresponding weldable layer formed thereon. The tool may move the fixing assembly to a predetermined height directly above the corresponding weldable layer on the workpiece and then releases or loosens the fixing assembly from the tool, so that the fixing assembly is fallen to the corresponding weldable layer. Then, the weldable layer on the locating member and the corresponding weldable layer on the workpiece are heated and welded to each other.

In the method according to the fifth aspect of the present disclosure, the engaging member and the fastening member can be integrally formed with each other,

In the method according to the fifth aspect of the present disclosure, the weldable layer and the corresponding weldable layer may be tin layers, copper layers, nickel layers, or zinc layers.

In the method according to the fifth aspect of the present disclosure, the weldable layer or the corresponding weldable layer may be a copper plating layer, on which a tin plating layer is further formed.

In the method according to the fifth aspect of the present disclosure, the tool picks up the fixing assembly from a carrier.

Therefore, with the above method of mounting a fixing assembly to a workpiece according to the present disclosure, the fixing assembly can be easily mounted to the workpiece.

### BRIEF DESCRIPTION OF THE DRAWINGS

FIG. 1 is a schematic vertical sectional view of a fastener structure according to a preferred embodiment of the present disclosure.

FIG. 2 is a schematic vertical sectional view of a fixing assembly according to a preferred embodiment of the present disclosure.

FIG. 3 is a first schematic view showing the assembling of a mating member of the fastener structure of FIG. 1 to a locating member according to a preferred embodiment of the present disclosure.

FIG. 4 is a second schematic view showing the assembling of the mating member to the locating member according to a preferred embodiment of the present disclosure.

FIG. 5 is a third schematic view showing the assembling of the mating member to the locating member according to a preferred embodiment of the present disclosure.

FIG. 6 is a schematic view showing a first retaining groove on the mating member and a second retaining groove on the locating member according to a preferred embodiment of the present disclosure.

FIG. 7 is a schematic view showing a mating member with retaining tabs according to a preferred embodiment of the present disclosure.

FIG. 8 is a first schematic view showing an outer peripheral surface of the mating member according to a preferred embodiment of the present disclosure.

FIG. 9 is a second schematic view showing an outer peripheral surface of the mating member according to a preferred embodiment of the present disclosure.

FIG. 10 is a schematic view showing an engaging member of the fastener structure according to a preferred embodiment of the present disclosure has an upper extended section.

FIG. 11 is a schematic view showing the engaging member of the fastener structure according to a preferred embodiment of the present disclosure has a lower extended section.

FIG. 12 is a schematic view showing the engaging member of the fastener structure according to a preferred embodiment of the present disclosure has an upper recessed section.

FIG. 13 is a schematic view showing the engaging member of the fastener structure according to a preferred embodiment of the present disclosure has a lower recessed section.

FIG. 14 is a first schematic view showing an outer peripheral surface of the engaging member of the fastener structure according to a preferred embodiment of the present disclosure.

FIG. 15 is a second schematic view showing an outer peripheral surface of the engaging member of the fastener structure according to a preferred embodiment of the present disclosure.

FIG. 16 is a third schematic view showing an outer peripheral surface of the engaging member of the fastener structure according to a preferred embodiment of the present disclosure.

FIG. 17 is a fourth schematic view showing an outer peripheral surface of the engaging member of the fastener structure according to a preferred embodiment of the present disclosure.

FIG. 18 is a fifth schematic view showing an outer peripheral surface of the engaging member of the fastener structure according to a preferred embodiment of the present disclosure.

FIG. 19 is a sixth schematic view showing an outer peripheral surface of the engaging member of the fastener structure according to a preferred embodiment of the present disclosure.

FIG. 20 is a seventh schematic view showing an outer peripheral surface of the engaging member of the fastener structure according to a preferred embodiment of the present disclosure.

FIG. 21 is an eighth schematic view showing an outer peripheral surface of the engaging member of the fastener structure according to a preferred embodiment of the present disclosure.

FIG. 22 is a ninth schematic view showing different outer peripheral surfaces for the engaging member of the fastener structure according to a preferred embodiment of the present disclosure.

FIG. 23 is a tenth schematic view showing an outer peripheral surface of the engaging member of the fastener structure according to a preferred embodiment of the present disclosure.

FIG. 24 is a first schematic view showing the assembling of the engaging member, the mating member and a fastening member of the fixing assembly according to a preferred embodiment of the present disclosure.

FIG. 25 is a second schematic view showing the assembling of the engaging member, the mating member and the fastening member of the fixing assembly according to a preferred embodiment of the present disclosure.

FIG. 26 is a schematic view showing a first mold according to a preferred embodiment of the present disclosure for connecting the mating member to the engaging member via plastic insertion molding.

FIG. 27 is a schematic view showing a first type of a fastening section of the fastening member according to a preferred embodiment of the present disclosure.

FIG. 28 is a schematic view showing a second type of the fastening section of the fastening member according to a preferred embodiment of the present disclosure.

FIG. 29 is a schematic view showing a third type of the fastening section of the fastening member according to a preferred embodiment of the present disclosure.

FIG. 30 is a schematic view showing a first type of an assembly of the engaging member, the mating member, the fastening member, the locating member and an elastic element according to a preferred embodiment of the present disclosure.

FIG. 31 is a schematic view showing a second type of the assembly of the engaging member, the mating member, the fastening member, the locating member and the elastic element according to a preferred embodiment of the present disclosure.

FIG. 32 is a schematic view showing a carrier, an assistant placement device and a covering member used in the present disclosure.

FIG. 33 is a first schematic view showing the fastening member according to a preferred embodiment of the present disclosure has a head portion located higher than a top of the mating member.

FIG. 34 is a second schematic view showing the fastening member according to a preferred embodiment of the present disclosure has a head portion located higher than a top of the mating member.

FIG. 35 is a schematic view showing the fastening member according to a preferred embodiment of the present disclosure has a head portion being flush with a top of the mating member.

FIG. 36 is a schematic view showing the fastening member according to a preferred embodiment of the present disclosure has a head portion located lower than a top of the mating member.

FIG. 37 is a schematic view showing a peripheral surface for the head portion of the fastening member according to a preferred embodiment of the present disclosure.

FIG. 38 is another schematic view showing a second mold according to a preferred embodiment of the present disclosure for integrally forming the engaging member and the fastening member and connecting the mating member to the engaging member via plastic insertion molding.

FIG. 39 is a schematic view showing the integrally formed fastening member and engaging member according to a preferred embodiment of the present disclosure.

FIG. 40 is a schematic view showing a third mold according to a preferred embodiment of the present disclosure for integrally forming the engaging member, the mating member and the fastening member.

FIG. 41 is a schematic view showing the integrally formed fastening member, engaging member and mating member according to a preferred embodiment of the present disclosure.

FIG. 42 is a first schematic view showing the use of the fixing assembly according to a preferred embodiment of the present disclosure.

FIG. 43 is a second schematic view showing the use of the fixing assembly according to a preferred embodiment of the present disclosure.

FIG. 44 is a first schematic view showing a first method for assembling the fixing assembly according to a preferred embodiment of the present disclosure.

FIG. 45 is a second schematic view showing the first method of assembling the fixing assembly according to a preferred embodiment of the present disclosure.

FIG. 46 is a third schematic view showing the first method of assembling the fixing assembly according to a preferred embodiment of the present disclosure.

FIG. 47 is a fourth schematic view showing the first method of assembling the fixing assembly according to a preferred embodiment of the present disclosure.

FIG. 48 is a first schematic view showing a second method of assembling the fixing assembly according to a preferred embodiment of the present disclosure.

FIG. 49 is a second schematic view showing the second method of assembling the fixing assembly according to a preferred embodiment of the present disclosure.

FIG. 50 is a first schematic view showing a third method of assembling the fixing assembly according to a preferred embodiment of the present disclosure.

FIG. 51 is a second schematic view showing the third method of assembling the fixing assembly according to a preferred embodiment of the present disclosure.

FIG. 52 is a schematic view showing an assistant assembling tool according to a preferred embodiment of the present disclosure.

FIG. 53 is a first schematic view showing a method of mounting a fixing assembly to a workpiece according to a preferred embodiment of the present disclosure.

FIG. 54 is a second schematic view showing the method of mounting a fixing assembly to a workpiece according to a preferred embodiment of the present disclosure.

### DETAILED DESCRIPTION OF THE INVENTION

To facilitate understanding of the objects, characteristics and effects of this present disclosure, embodiments together with the attached drawings for the detailed description of the present disclosure are provided. It is noted the present disclosure can be implemented or applied in other embodiments, and many changes and modifications in the described embodiments can be carried out without departing from the spirit of the disclosure, and it is also understood that the preferred embodiments are only illustrative and not intended to limit the present disclosure in any way. For the purpose of easy to understand, elements that are the same in the preferred embodiments are denoted by the same reference numerals.

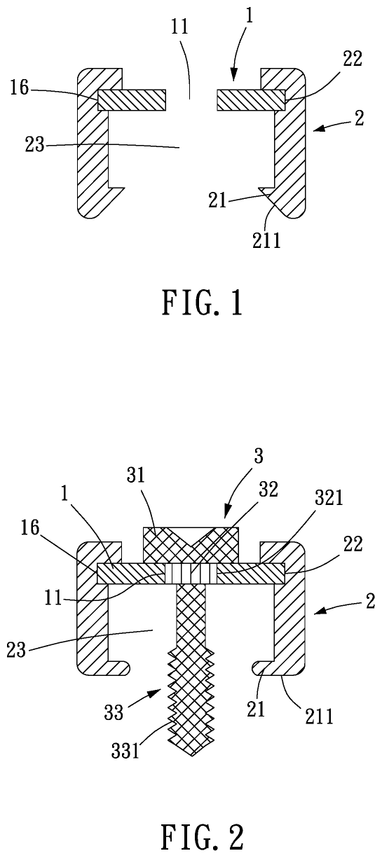

Please refer to FIGS. 1 and 2, in which a fastener structure for fixing assembly provided according to a first aspect of the present disclosure is shown. The fastener structure includes an engaging member 1 and a mating member 2. The engaging member 1 is connected to the mating member 2, and is used to engage with a fastening member 3. With these arrangements, the fastener structure for fixing assembly according to the present disclosure can be formed with a simple structure.

Please refer to FIG. 1 again. In the above-described fastener structure for fixing assembly, the mating member 2 can be a hollow cylindrical body; or an assembly of the engaging member 1 and the mating member 2 can be a hollow cylindrical body. The hollow cylindrical body internally defines a receiving space 23. The engaging member 1 can be in the form of a plate and has an outer peripheral surface adapted to be correspondingly joined with an engaging section 22 of the mating member 2. The engaging section 22 can be differently configured to be protruded, recessed, grooved, serrated, polygonal-shaped or step-shaped. In the case of a polygonal-shaped engaging section 22, it may be an odd-sided polygon or an even-sided polygon.

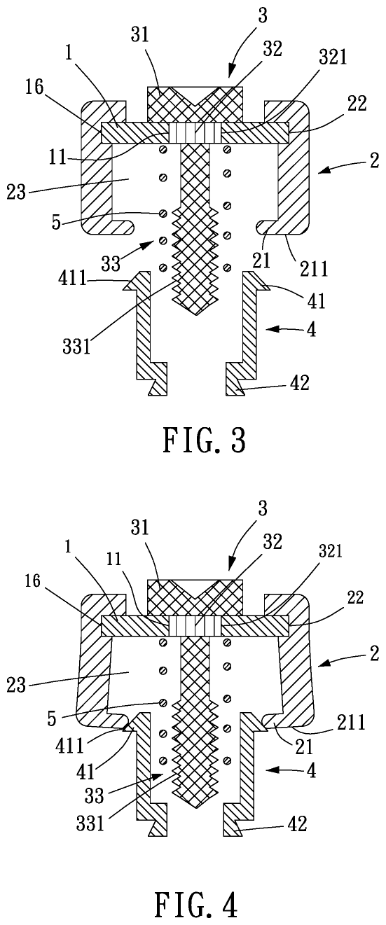

Please refer to FIGS. 1 to 5. As shown, in the above-described fastener structure for fixing assembly, the mating member 2 can have a first inner retaining section 21 formed around a bottom edge thereof, and the first inner retaining section 21 is used for movably connecting to a locating member 4. The locating member 4 is movable inside and outside the receiving space 23. The first inner retaining section 21 can be a flange radially extended into the mating member 2, and the locating member 4 can be a hollow cylindrical body.

Referring to FIGS. 1 to 4, in the above-described fastener structure for fixing assembly, a bottom of the first inner retaining section 21 forms a first pressing surface 211, which can be a bevel surface, a flat surface, a curved surface or a cambered surface. When connecting the mating member 2 to the locating member 4, the first pressing surface 211 can press against the locating member 4.

Referring to FIGS. 1 to 5, in the above-described fastener structure for fixing assembly, the first inner retaining section 21 can be made of a plastic material with elasticity. Therefore, when connecting the mating member 2 to the locating member 4, the mating member 2 is elastically deformable.

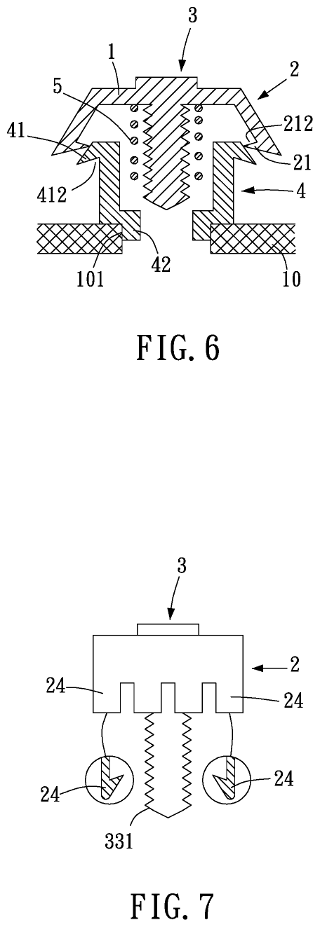

As shown in FIG. 6, in the above-described fastener structure for fixing assembly, the first inner retaining section 21 can have a first retaining groove 212 formed thereat for stably but detachably retaining the locating member 4 thereto.

Please refer to FIG. 7. In the above-described fastener structure for fixing assembly, the mating member 2 can have a plurality of retaining tabs 24 for conveniently movably retaining the locating member 4 thereto.

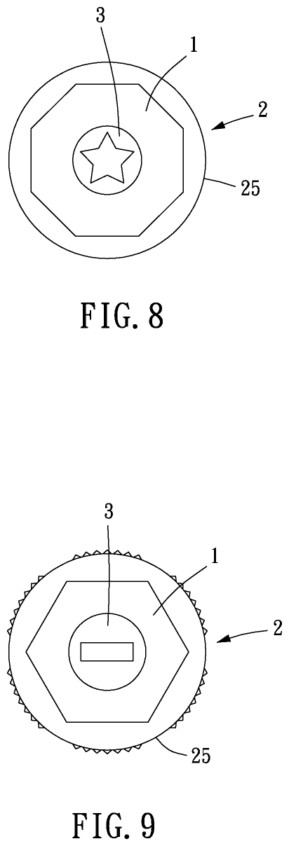

Please refer to FIGS. 8 and 9. In the above-described fastener structure for fixing assembly, the mating member 2 has an outer peripheral surface 25, which can be a smooth surface, as shown in FIG. 8, or a toothed surface, as shown in FIG. 9.

Alternatively, the outer peripheral surface 25 can be serrated or embossed. Therefore, a user can conveniently hold the mating member 2 at the outer peripheral surface 25 thereof.

Please refer to FIGS. 1 and 2 again. In the above-described fastener structure for fixing assembly, the engaging member 1 can have an insertion-hole section 11, through which the fastening member 3 is extended to be held in place. The insertion-hole section 11 can be a through hole having a diameter slightly smaller than a diameter of an assembling section 32 of the fastening member 3.

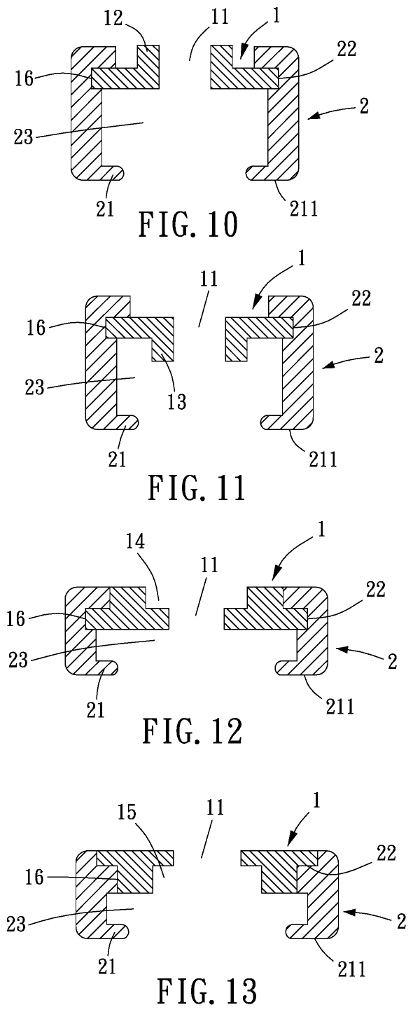

Please refer to FIGS. 10 to 13. In the above-described fastener structure for fixing assembly, the insertion-hole section 11 of the engaging member 1 can be provided with an upper extended section 12 (see FIG. 10), a lower extended section 13 (see FIG. 11), an upper recessed section 14 (see FIG. 12), or a lower recessed section 15 (see FIG. 13), so that the fastening member 3 can be conveniently located in place in the insertion-hole section 11.

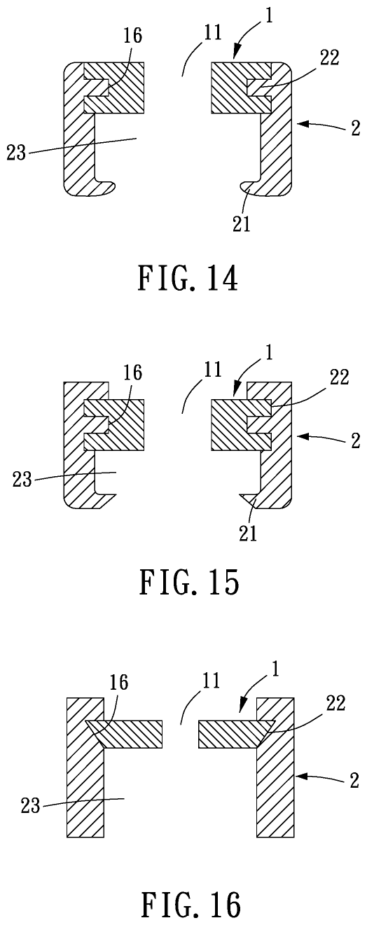

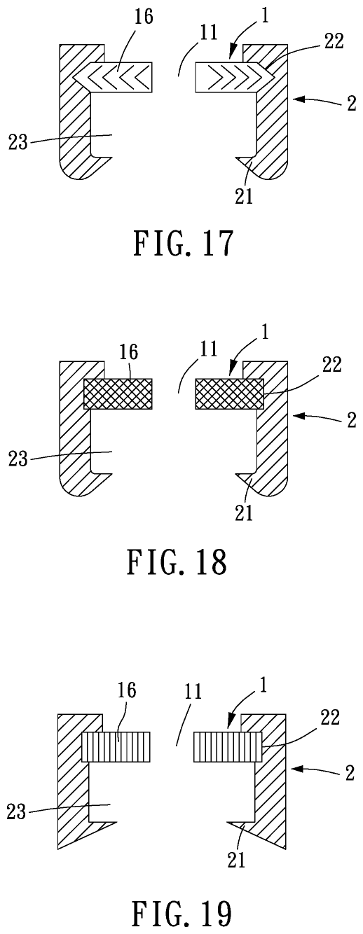

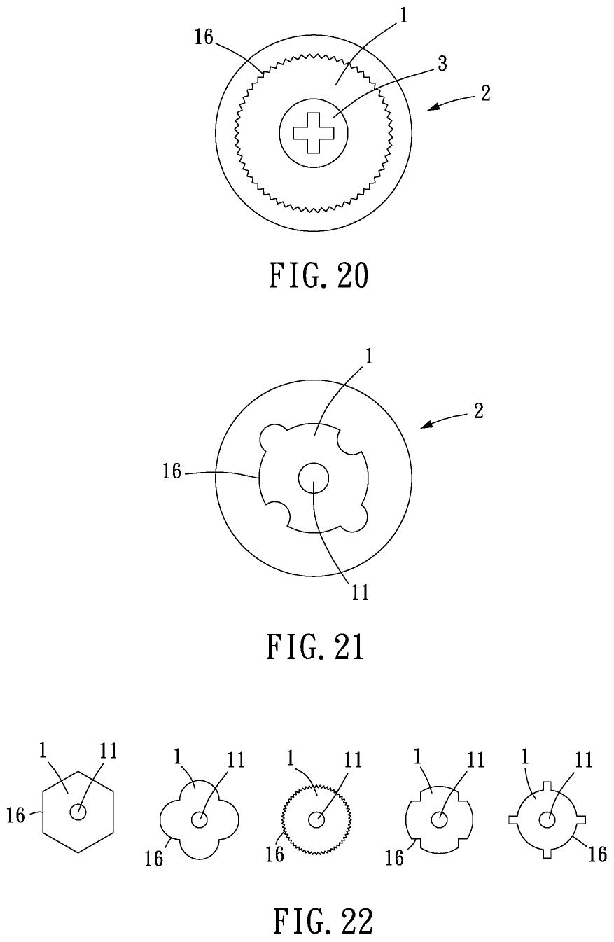

Referring to FIGS. 14 to 22, in the above-described fastener structure for fixing assembly, the engaging member 1 has an outer peripheral surface 16, which can be embossed, serrated or toothed, or be provided with recessed portions or protruded portions, or be a flat surface, a bevel surface, a curved surface or a cambered surface, so that the engaging member 1 can be correspondingly connected to the mating member 2.

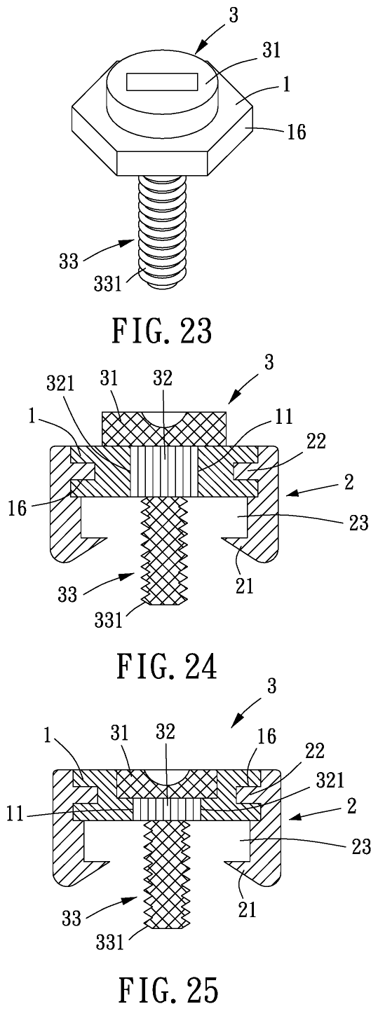

Please refer to FIG. 23. In the above-described fastener structure for fixing assembly, the outer peripheral surface 16 of the engaging member 1 can be in the form of an even-sided polygon or an odd-sided polygon for connecting to the mating member 2.

Please refer to FIGS. 14, 15, 24 and 25. In the above-described fastener structure for fixing assembly, the engaging member 1 can be connected at a lower portion and a side portion of the outer peripheral surface 16 to the mating member 2 (see FIG. 14), or the engaging member 1 can be connected at an upper portion, a lower portion and a side portion of the outer peripheral surface 16 to the mating member 2 (see FIG. 15). Alternatively, the engaging member 1 can be connected at an upper portion, a lower portion or a side portion of the outer peripheral surface 16 to the mating member 2. Alternatively, the engaging member 1 can be connected at an upper and a lower portion of the outer peripheral surface 16 to the mating member 2, or the engaging member 1 can be connected at an upper and a side portion of the outer peripheral surface 16 to the mating member 2.

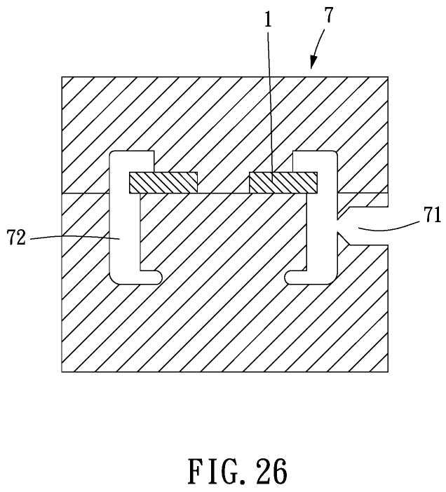

Please refer to FIG. 26. In the above-described fastener structure for fixing assembly, the mating member 2 can be connected to the engaging member 1 by way of plastic insertion molding. In this case, a first mold 7 is provided. The first mold 7 has a gate 71 and a mating-member receiving space 72, which are communicable with each other. The engaging member 1 is disposed in the first mold 7 and is connected to the mating-member receiving space 72. Via the gate 71, a molten plastic material is injected into the mating-member receiving space 72 to form the mating member 2, which is connected to the engaging member 1 in the first mold 7.

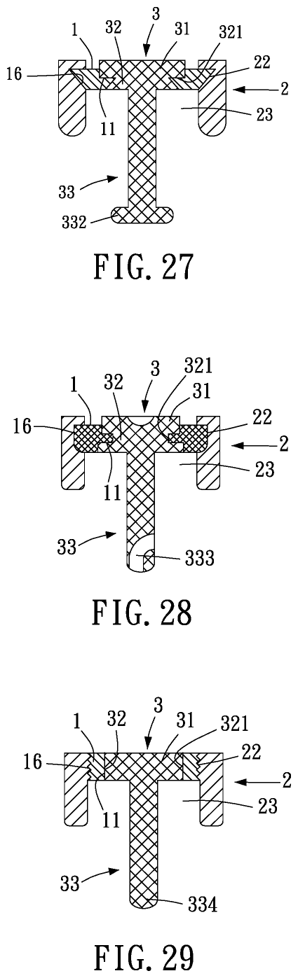

Please refer to FIGS. 27 to 29. In the above-described fastener structure for fixing assembly, the mating member 2 can be connected to the engaging member 1 by way of thermal bonding, riveting, expanded connection, glue bonding, screwing or welding.

In the above-described fastener structure for fixing assembly, the engaging member 1 can be made of a plastic material or a metal material, and the mating member 2 can be made of a plastic material or a metal material.

Please refer to FIG. 32. In the above-described fastener structure for fixing assembly, a carrier 8 can be further included. The carrier 8 has a plurality of receiving compartments 81 formed thereon for respectively holding one fastener structure therein. The carrier 8 can be in the form of a tray or a belt.

Please refer to FIG. 32 again. In the above-described fastener structure for fixing assembly, an assistant placement device 6 can be further included. The assistant placement device 6 is disposed on a top of the fastener structure, so that a placement apparatus can conveniently pick and place the fastener structure with the help of the assistant placement device 6. The assistant placement device 6 can have a magnetic property or a sticky property, or can be a fastening device.

Please refer to FIG. 32 again. In the above-described fastener structure for fixing assembly, the carrier 8 can have a covering member 9 for covering the fastener structures disposed on the carrier 8 and accordingly protecting the fastener structures against undesired dropping or contamination.

Please refer to FIG. 2 again, in which a fixing assembly provided according to a second aspect of the present disclosure is shown. The fixing assembly includes a fastening member 3 and the above-described fastener structure. The fastening member 3 includes a head portion 31, an assembling section 32 and a fastening section 33, which are sequentially connected to one another. And, the assembling section 32 is assembled to the engaging member 1. With these arrangements, the fixing assembly according to the present disclosure can be formed with a simple structure.

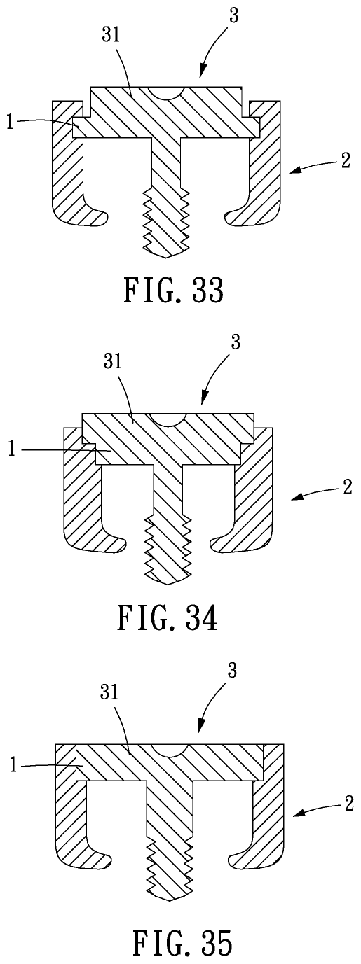

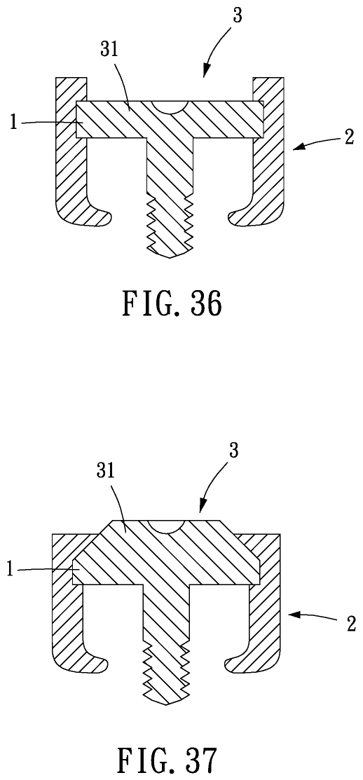

Please refer to FIGS. 33 to 36. In the above-described fixing assembly, the head portion 31 of the fastening member 3 can be located higher than, flush with, or located lower than a top of the mating member 2.

Referring to FIG. 37, in the above-described fixing assembly, the head portion 31 of the fastening member 3 has an outer peripheral surface, which can be a bevel surface, a cambered surface, or a curved surface.

Please refer to FIG. 2 and FIGS. 27 to 31 at the same time. In the above-described fixing assembly, the assembling section 32 of the fastening member 3 has an outer peripheral surface 321, which can be embossed, serrated or toothed, or be provided with recessed portions or protruded portions, or in the form of a flat surface, a bevel surface, a curved surface or a cambered surface, so that the assembling section 32 can be correspondingly assembled to the engaging member 1 by way of riveting, fastening, expanded connection, screwing, welding, glue bonding or thermal bonding.

Please refer to FIG. 23 along with FIGS. 33 to 39 and FIGS. 50 to 51. In the above-described fixing assembly, the fastening member 3 can be integrally formed with the engaging member 1 by way of machining, forging, stamping, plastic injection molding or metal injection molding.

Please refer to FIG. 2 along with FIGS. 27 to 29. In the above-described fixing assembly, the assembling section 32 of the fastening member 3 can be in the form of male threads, female threads, a male retainer, a female retainer or a stem.

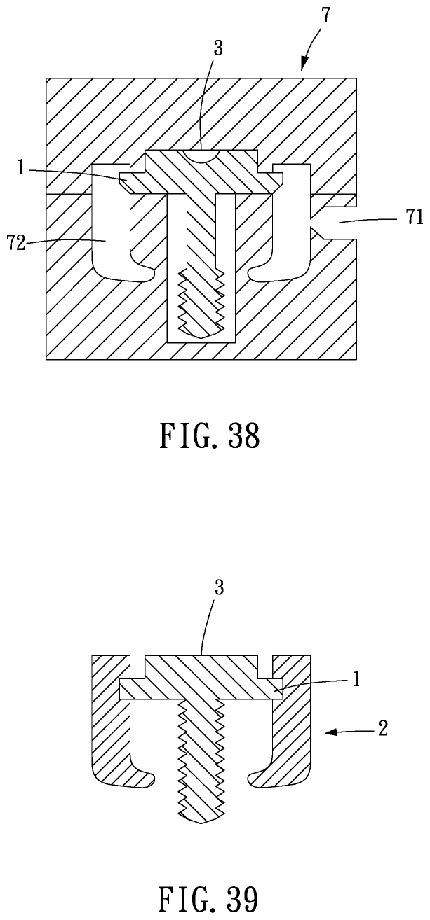

Referring to FIGS. 38 and 39, in the above-described fixing assembly, the engaging member 1 and the fastening member 3 can be integrally formed, and the mating member 2 can be connected to the engaging member 1 by way of plastic insertion molding. In this case, a second mold 7 is provided. The second mold 7 has a gate 71 and a mating-member receiving space 72, which are communicable with each other. A structure of the integrally formed engaging member 1 and fastening member 3 is disposed in the second mold 7 with the engaging member 1 being connected to the mating-member receiving space 72. Via the gate 71, a molten plastic material is injected into the mating-member receiving space 72 to form the mating member 2, which is connected to the engaging member 1 in the second mold 7.

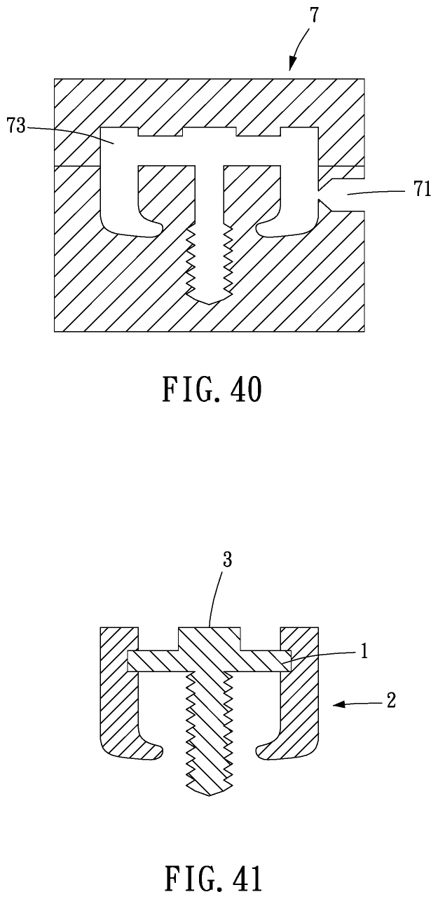

Please refer to FIGS. 40 and 41. In the above-described fixing assembly, the fastening member 3, the engaging member 1 and the mating member 2 can be integrally formed with one another by way of machining, forging, stamping, plastic injection molding or metal injection molding. In this case, a third mold 7 is further provided. The third mold 7 has a gate 71 and a fixing-assembly receiving space 73, which are communicable with each other. Via the gate 71, a molten plastic material is injected into the fixing-assembly receiving space 73 to integrally form the fixing assembly. Further, the engaging member 1, the mating member 2 and the fastening member 3 can be formed as a module.

Referring to FIG. 32, in the above-described fixing assembly, a carrier 8 can be further included. The carrier 8 has a plurality of receiving compartments 81 formed thereon for respectively holding one fixing assembly therein. The carrier 8 can be in the form of a tray or a belt.

Please refer to FIG. 32 again. In the above-described fixing assembly, an assistant placement device 6 can be further included. The assistant placement device 6 is disposed on a top of the fixing assembly, so that a placement apparatus can conveniently pick and place the fixing assembly with the help of the assistant placement device 6. The assistant placement device 6 can have a magnetic property or a sticky property, or can be a fastening device.

Please refer to FIG. 32 again. In the above-described fixing assembly, the carrier 8 can have a covering member 9 for covering the fixing assemblies disposed on the carrier 8 and accordingly protecting the fixing assemblies against undesired dropping or contamination.

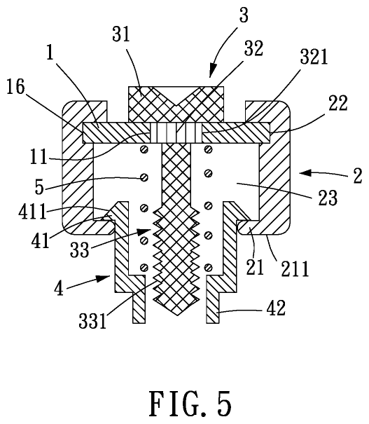

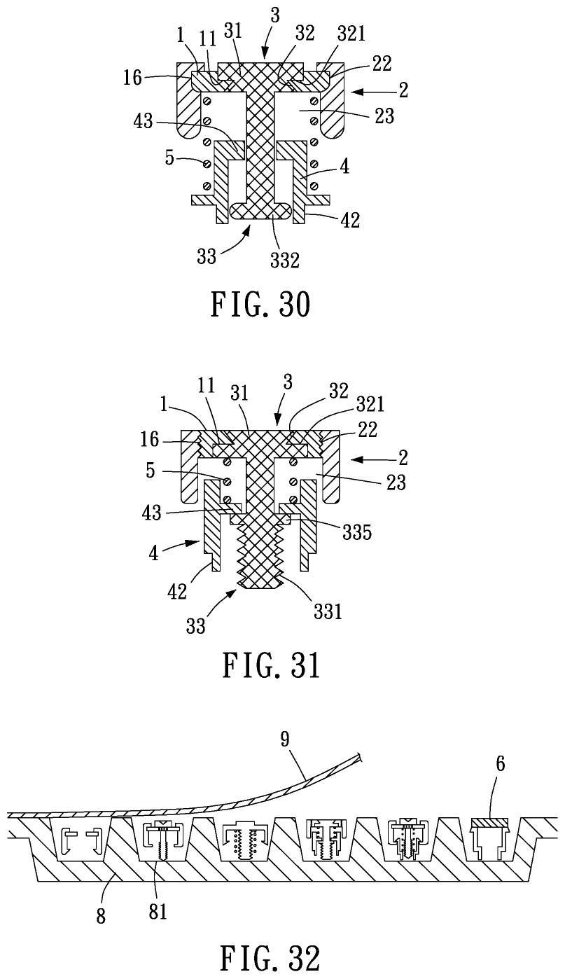

Please refer to FIG. 5 along with FIGS. 30 and 31. The above-described fixing assembly further includes a locating member 4. The locating member 4 is movably connected to the mating member 2 or the fastening member 3.

Please refer to FIG. 5. In the above-described fixing assembly, the locating member 4 can have an outer retaining section 41 for movably connecting to the first inner retaining section 21 of the mating member 2. The outer retaining section 41 can be a flange radially outward extended from the locating member 4.

Referring to FIG. 6, in the above-described fixing assembly, the locating member 4 can have a second retaining groove 412 formed at the outer retaining section 41 for stably but detachably engaging with the first inner retaining section 21 on the mating member 2.

Referring to FIG. 5 again, in the above-described fixing assembly, a top of the outer retaining section 41 of the locating member 4 forms a second pressing surface 411, which can be a bevel surface, a flat surface, a curved surface or a cambered surface.

When connecting the locating member 4 to the mating member 2, the second pressing surface 411 can press against the first inner retaining section 21 of the mating member 2 to push the first pressing surface 211 radially outward.

Please refer to FIG. 5 along with FIGS. 30, 31, 42 and 43. In the above-described fixing assembly, the locating member 4 can have a locating section 42, which can be connected to a workpiece 10 by way of riveting, fastening, expanded connection, screwing, welding or glue bonding.

In the above-described fixing assembly, the engaging member 1, the mating member 2, the locating member 4 and the fastening member 3 can be assembled into a module. In addition, the engaging member 1, the mating member 2, the locating member 4, the fastening member 3 and the workpiece 10 can also be assembled into a module with the workpiece 10 being connected to the locating member 4.

Referring to FIGS. 30 and 31 again, in the above-described fixing assembly, the locating member 4 can have a second inner retaining section 43 for movably connecting to the fastening member 3. The second inner retaining section 43 can be a flange radially extended into the locating member 4. And, the second inner retaining section 43 can be movably connected to the fastening section 33 of the fastening member 3 or be movably connected to a retaining flange 335 of the fastening member 3. The retaining flange 335 is located above the fastening section 33.

Referring to FIG. 32 again, in the above-described fixing assembly, a carrier 8 can be further included. The carrier 8 has a plurality of receiving compartments 81 formed thereon for respectively holding one fixing assembly therein. The carrier 8 can be in the form of a tray or a belt

Please refer to FIG. 32 again. In the above-described fixing assembly, an assistant placement device 6 can be further included. The assistant placement device 6 is disposed on a top of the fixing assembly, so that a placement apparatus can conveniently pick and place the fixing assembly with the help of the assistant placement device 6. The assistant placement device 6 can have a magnetic property or a sticky property, or can be a fastening device.

Please refer to FIG. 32 again. In the above-described fixing assembly, the carrier 8 can have a covering member 9 for covering the fixing assemblies disposed on the carrier 8 and accordingly protecting the fixing assemblies against undesired dropping or contamination.

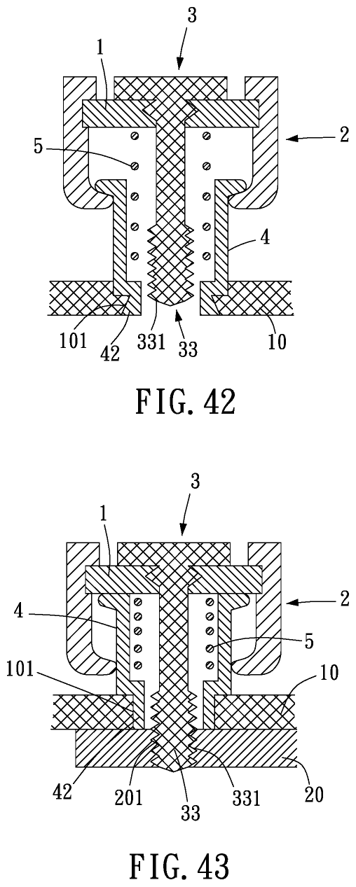

Please refer to FIG. 5 along with FIGS. 42 and 43 again. The above-described fixing assembly further includes an elastic element 5, which has an end pressed against the engaging member 1 or the mating member 2 and another end pressed against the locating member 4. With these arrangements, an assembly of the engaging member 1, the mating member 2 and the fastening member 3 is movable forward or backward relative to the locating member 4.

In the above-described fixing assembly, the engaging member 1, the mating member 2, the locating member 4, the fastening member 3 and the elastic element 5 can be assembled into a module. In addition, the engaging member 1, the mating member 2, the locating member 4, the fastening member 3, the elastic element 5 and the workpiece 10 can also be assembled into a module with the workpiece 10 being connected to the locating member 4.

Please refer to FIGS. 42 and 43 again. To use the above-described fixing assembly, first fit the locating section 42 of the locating member 4 in a first fastening hole 101 on the workpiece 10. Then, downward press or turn the fastening member 3 for the fastening section 33 thereof to engage with a second fastening hole 201 on another workpiece 20, so that the two workpieces 10, 20 are fastened together.

Referring to FIG. 32 again, in the above-described fixing assembly, a carrier 8 can be further included. The carrier 8 has a plurality of receiving compartments 81 formed thereon for respectively holding one fixing assembly therein. The carrier 8 can be in the form of a tray or a belt.

Please refer to FIG. 32 again. In the above-described fixing assembly, an assistant placement device 6 can be further included. The assistant placement device 6 is disposed on a top of the fixing assembly, so that a placement apparatus can conveniently pick and place the fixing assembly with the help of the assistant placement device 6. The assistant placement device 6 can have a magnetic property or a sticky property, or can be a fastening device.

Please refer to FIG. 32 again. In the above-described fixing assembly, the carrier 8 can have a covering member 9 for covering the fixing assemblies disposed on the carrier 8 and accordingly protecting the fixing assemblies against undesired dropping or contamination.

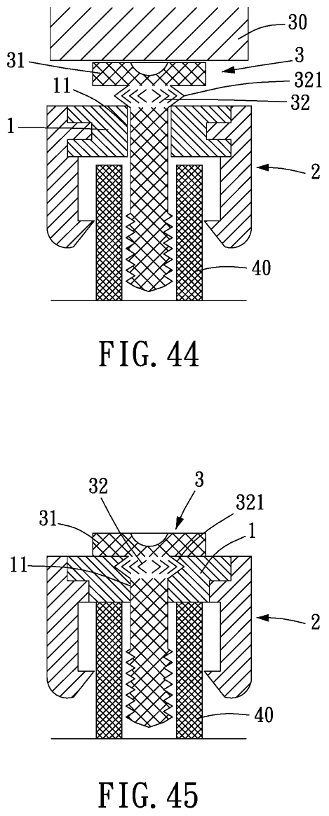

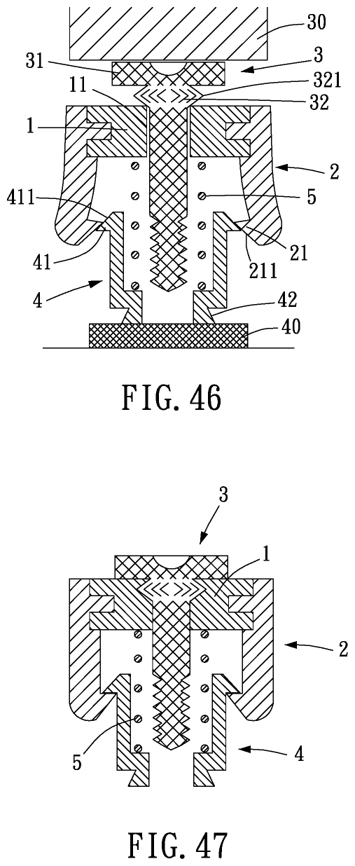

Please refer to FIGS. 44 to 47, in which a first method of assembling a fixing assembly provided according to a third aspect of the present disclosure is shown. The fixing assembly to be assembled is the same as the above-described fixing assembly. To assemble the fixing assembly according to the first method, first connect the engaging member 1 to the mating member 2 and use a supporting member 40 to support and hold the connected engaging member 1 and mating member 2 in place. Then, use a pressing device 30 to apply a pressing force on the fastening member 3, so that the assembling section 32 of the fastening member 3 is forced through the insertion-hole section 11 of the engaging member 1 and assembled to the engaging member 1. Alternatively, first integrally form the engaging member 1 and the fastening member 3 and then connect the integrally formed engaging member 1 and fastening member 3 to the mating member 2. Finally, use the pressing device 30 to apply a pressing force on the fastening member 3, so that the first inner retaining section 21 of the mating member 2 is pressed against the outer retaining section 41 of the locating member 4 to be radially outward expanded, bringing the first inner retaining section 21 of the mating member 2 to be movably connected to an outer side of the outer retaining section 41 of the locating member 4, or bringing the fastening member 3 to be movably connected to the second inner retaining section 43 of the locating member 4. Further, the engaging member 1 and the mating member 2 can be integrally formed. Accordingly, with the first method of the present disclosure, it is able to assemble the fixing assembly through simple steps.

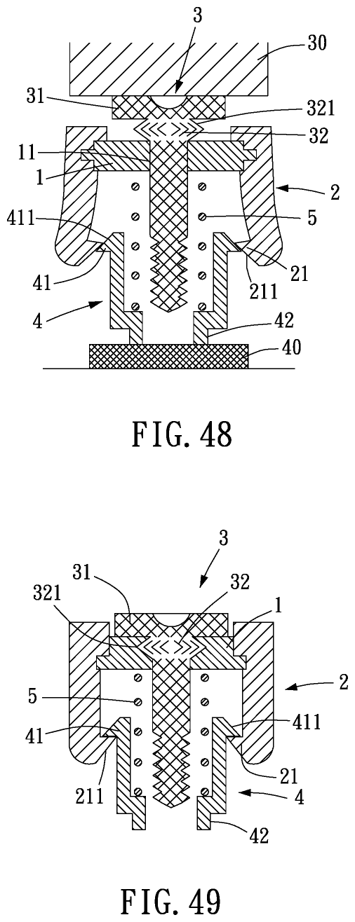

Please refer to FIGS. 48 and 49. In a second method of assembling a fixing assembly provided according to the third aspect of the present disclosure, first connect the engaging member 1 to the mating member 2. Then, use a pressing device 30 to apply a pressing force on the fastening member 3, so that the assembling section 32 of the fastening member 3 is forced through the insertion-hole 11 of the engaging member 1 and the first inner retaining section 21 of the mating member 2 is pressed against the outer retaining section 41 of the locating member 4. Finally, the assembling section 32 of the fastening member 3 is assembled to the insertion-hole section 11 of the engaging member 1 and the first inner retaining section 21 of the mating member 2 is radially outward expanded at the same time, bringing the first inner retaining section 21 of the mating member 2 to be movably connected to an outer side of the outer retaining section 41 of the locating member 4, or bringing the fastening member 3 to be movably connected to the second inner retaining section 43 of the locating member 4. Further, the engaging member 1 and the mating member 2 can be integrally formed. Accordingly, with the second method of the present disclosure, it is able to assemble the fixing assembly through simple steps.

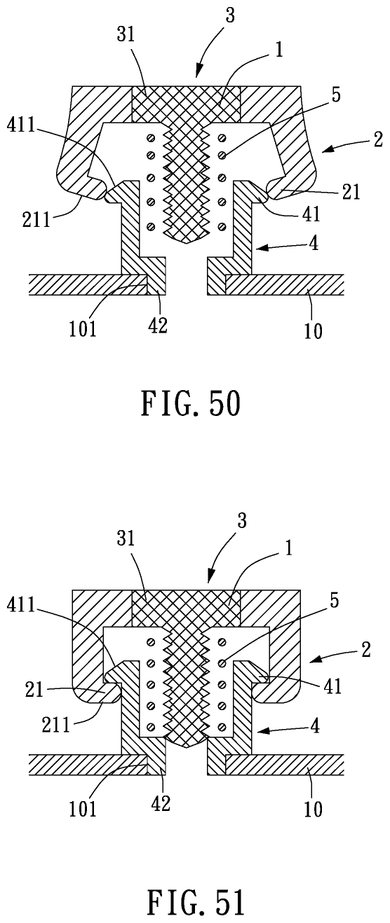

Please refer to FIGS. 50 and 51, in which a third method of assembling a fixing assembly provided according to a fourth aspect of the present disclosure is shown. The fixing assembly to be assembled is the same as the above-described fixing assembly. To assemble the fixing assembly according to the third method, first connect the engaging member 1, the mating member 2 and the fastening member 3 together, or integrally form the engaging member 1, the mating member 2 and the fastening member 3, or integrally form the engaging member 1 and the fastening member 3 and connect the integrally formed engaging member 1 and fastening member 3 to the mating member 2; and connect the locating member 4 to a workpiece 10 by way of riveting, fastening, expanded connection, screwing, welding or glue bonding to form a module. Then, use a pressing device 30 to apply a pressing force on fastening member 3, so that the first inner retaining section 21 of the mating member 2 is pressed against the outer retaining section 41 of the locating member 4 to be radially outward expanded, bringing the first inner retaining section 21 of the mating member 2 to be movably connected to an outer side the outer retaining section 41 of the locating member 4, or bringing the fastening member 3 to be movably connected to the second inner retaining section 43 of the locating member 4. Accordingly, with the third method of the present disclosure, it is able to assemble the fixing assembly through simple steps.

Please refer to FIGS. 44 to 51. In the first and second methods of assembling a fixing assembly according to the third aspect of the present disclosure and in the third method of assembling a fixing assembly according to the fourth aspect of the present disclosure, the first inner retaining section 21 of the mating member 2 is made of a plastic material with elasticity. Before the first inner retaining section 21 of the mating member 2 can be movably connected to the outer retaining section 41 of the locating member 4, the first inner retaining section 21 is first radially outward expanded to be diametrically larger than or equal to the outer retaining section 41 and can therefore move across the outer retaining section 41. Once the first inner retaining section 21 has moved across the outer retaining section 41, it immediately elastically restores to its non-expanded position and is movably connected to the outer side of the outer retaining section 41 of the locating member 4.

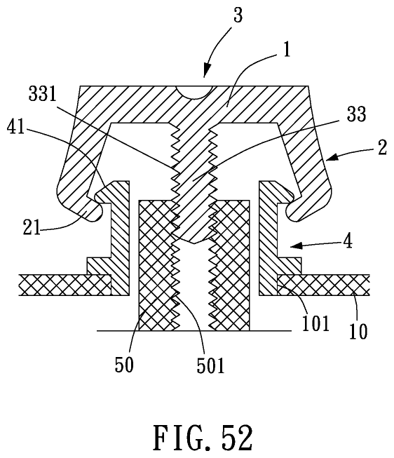

Please refer to FIG. 52. In the third method of assembling a fixing assembly according to the fourth aspect of the present disclosure, an assistant assembling tool 50 can be provided and used to move the fastening section 33 of the fastening member 3, so that the first inner retaining section 21 of the mating member 2 is brought to be movably connected to the outer side of the outer retaining section 41 of the locating member 4 or the fastening member 3 is brought to be movably connected to the locating member 4.

As can be seen in FIG. 52, in the third method of assembling a fixing assembly according to the fourth aspect of the present disclosure, the assistant assembling tool 50 is provided with internal threads 501 that mesh with external threads 331 provided on the fastening section 33 of the fastening member 3 to move the latter. Alternatively, the assistant assembling tool 50 can be provided with external threads, a through hole, protruded portions or recessed portions. For instance, when the fastening member 3 is screwed into the assistant assembling tool 50 with the external threads 331 meshing with the internal threads 501, the first inner retaining section 21 of the mating member 2 can be brought to press against the outer retaining section 41 of the locating member 4 and be radially outward expanded, so that the first inner retaining section 21 can move across the outer retaining section 41 to be movably connected to the outer side of the outer retaining section 41.

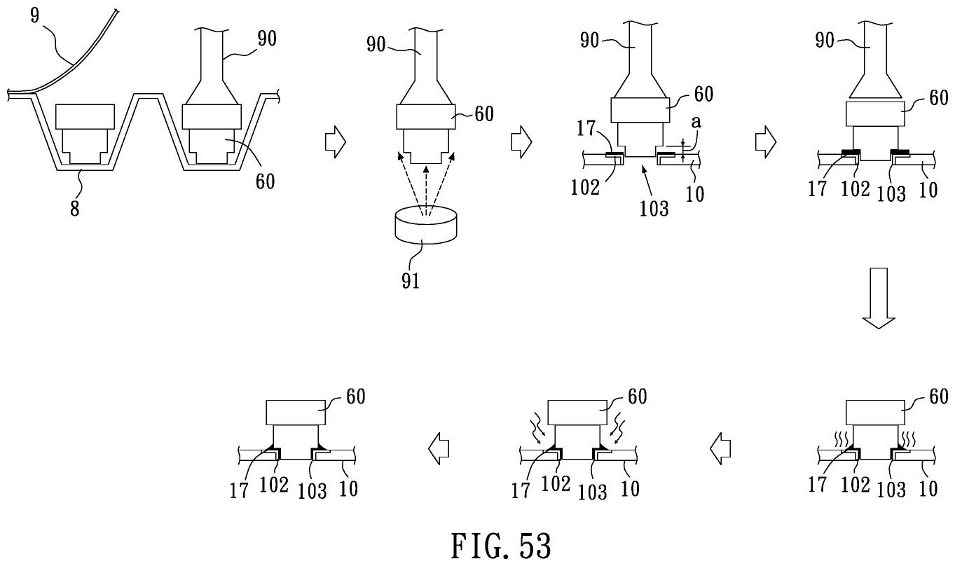

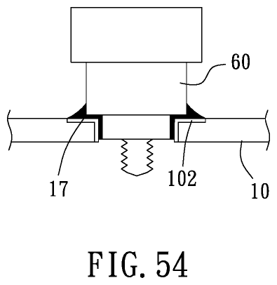

Please refer to FIGS. 53 and 54, in which a method of mounting a fixing assembly 60 to a workpiece 10 provided according to a fifth aspect of the present disclosure is shown. As the fixing assembly described in the previous aspects of the present disclosure, the fixing assembly 60 includes an engaging member, a mating member and a fastening member; and the engaging member is correspondingly connected to the mating member and to the fastening member. The fixing assembly 60 may be placed in a carrier 8 and picked up from the carrier using a tool 90. A comparison device 91 is provided to compare the fixing assembly 60 with a mounting position 103 on the workpiece 10 or a mounting distance between the fixing assembly 60 and the workpiece 10. Based on comparison information provided by the comparison device 91, the tool 90 moves the fixing assembly 60 to a predetermined height “a” directly above the mounting position 103 on the workpiece 10, and then releases or loosens the fixing assembly 60 from the tool 90, so that the fixing assembly 60 is fallen to the mounting position 103 and can be mounted to the workpiece 10. Alternatively, the fixing assembly 60 can be movably connected to the locating member described in the previous aspects of the present disclosure. Further, the engaging member and the fastening can be integrally formed with each other.

In the method according to the fifth aspect of the present disclosure, the fixing assembly 60 may include a weldable layer 17 and the workpiece 10 may be a printed circuit board (PCB) and have a corresponding weldable layer 102 formed thereon. The tool 90 may move the fixing assembly 60 to a predetermined height “a” directly above the corresponding weldable layer 102 on the workpiece 10 and then releases or loosens the fixing assembly 60 from the tool 9, so that the fixing assembly 60 is fallen to the corresponding weldable layer 102. Then, the weldable layer 17 of the fixing assembly 60 and the corresponding weldable layer 102 of the workpiece 10 are heated and welded to each other, causing the fixing assembly 60 to be fixedly welded to the workpiece 10.

Alternatively, in the case the fixing assembly 60 is movably connected to the locating member, the weldable layer 17 can be otherwise provided on the locating member. Further, the engaging member and the fastening member can be integrally formed with each other.

In the method according to the fifth aspect of the present disclosure, the tool 90 can be a vacuum suction device, a pick-up device, a retaining device, a magnetic suction device, or a robotic arm.

In the method according to the fifth aspect of the present disclosure, the comparison device 91 may be a charge-coupled device (CCD), a visual comparison device, an image comparison device, a distance comparison device, or a computer comparison device.

In the method according to the fifth aspect of the present disclosure, the weldable layer 17 and the corresponding weldable layer 102 are tin layers, copper layers, nickel layers or zinc layers. Alternatively, the weldable layer 17 or the corresponding weldable layer can be a copper plating layer, on which a tin plating layer is further formed.

While the present disclosure has been described by means of specific embodiments, numerous modifications and variations could be made thereto by those skilled in the art without departing from the scope and spirit of the present disclosure set forth in the claims.

What is claimed is:

1. A method of mounting a fixing assembly to a workpiece, the fixing assembling including an engaging member, a mating member and a fastening member, and the engaging member being correspondingly connected to the mating member and to the fastening member; comprising the following steps:
providing a tool to pick up the fixing assembly;
providing a comparison device to compare the fixing assembly with a mounting position on the workpiece or a distance between the fixing assembly and the mounting position on the workpiece;
moving the fixing assembly to a predetermined height directly above the mounting position on the workpiece via the tool based on comparison information provided by the comparison device; and
releasing or loosening the fixing assembly from the tool, so that the fixing assembly is fallen to the mounting position on the workpiece.

2. The method according to claim 1, wherein the fixing assembly is movably connected to a locating member, which is connected to the workpiece.

3. The method according to claim 1, wherein the engaging member and the fastening member are integrally formed with each other.

4. The method according to claim 1, wherein the tool is selected from the group consisting of a vacuum suction device, a pick-up device, a retaining device, a magnetic suction device and a robotic arm.

5. The method according to claim 1, wherein the comparison device is selected from the group consisting of a charge-coupled device (CCD), a visual comparison device, an image comparison device, a distance comparison device and a computer comparison device.

6. The method according to claim 1, wherein the fixing assembly includes a weldable layer, and the workpiece is a printed circuit board (PCB) and has a corresponding weldable layer formed on the mounting position; the fixing assembly being moved by the tool to a predetermined height directly above the corresponding weldable layer on the workpiece and being released or loosened from the tool to fall on the corresponding weldable layer on the workpiece; and the weldable layer on the fixing assembly and the corresponding weldable layer on the workpiece being heated and welded to each other.

7. The method according to claim 2, wherein the locating member is provided with a weldable layer, and the workpiece is a printed circuit board (PCB) and has a corresponding weldable layer formed on the mounting position; the fixing assembly being moved by the tool to a predetermined height directly above the corresponding weldable layer on the workpiece and being released or loosened from the tool to fall on the corresponding weldable layer on the workpiece; and the weldable layer on the locating member and the corresponding weldable layer on the workpiece being heated and welded to each other.

8. The method according to claim 7, wherein the engaging member and the fastening member are integrally formed with each other.

9. The method according to claim 6, wherein the weldable layer and the corresponding weldable layer are selected from the group consisting of tin layers, copper layers, nickel layers and zinc layers.

10. The method according to claim 7, wherein the weldable layer and the corresponding weldable layer are selected from the group consisting of tin layers, copper layers, nickel layers and zinc layers.

11. The method according to claim 8, wherein the weldable layer and the corresponding weldable layer are selected from the group consisting of tin layers, copper layers, nickel layers and zinc layers.

12. The method according to claim 6, wherein one of the weldable layer and the corresponding weldable layer is a copper plating layer, on which a tin plating layer is further formed.

13. The method according to claim 7, wherein one of the weldable layer and the corresponding weldable layer is a copper plating layer, on which a tin plating layer is further formed.

14. The method according to claim 8, wherein one of the weldable layer and the corresponding weldable layer is a copper plating layer, on which a tin plating layer is further formed.

15. The method according to claim 1, wherein the fixing assembly is picked up by the tool from a carrier.
